(19) United States
(12) Patent Application Publication
(10) Pub. No.: US 2005/0231049 A1
(43) Pub. Date: Oct. 20, 2005

(54) Fan with brushless direct current motor

(75) Inventors: Chin-Long Ku, Tu-Cheng (TW); Chin-Wen Yeh, Tu-Cheng (TW); Chia-Mou Liu, Tu-Cheng (TW)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: Foxconn Technology Co., Ltd., Tu-Cheng City (TW)

(21) Appl. No.: 11/093,194

(22) Filed: Mar. 29, 2005

(30) Foreign Application Priority Data
Apr. 17, 2004 (CN) 200420045004.3

(51) Int. Cl. H02K 11/00; H05K 1/11; H05K 1/14

(52) U.S. Cl. 310/68 R

(57) ABSTRACT

A fan includes a stator including a stator coil assembly (5) having a plurality of coils, and a circuit board (6) having a circuit to control the electrical current flowing through the coils, and a rotor including a hub (31) carrying a permanent magnet (33) facing to the stator coil assembly. At least two sides of the circuit board are substantially straight so that a plurality of such printed circuit boards can be compactly laid out side by side on a substrate (600) for producing the printed circuit boards.

### TECHNICAL FEILD

The present invention relates generally to fans, and more particularly to a fan which is driven by a brushless direct current motor.

### BACKGROUND

A conventional brushless direct current fan comprises a stator and a rotor rotatable with respect to the stator. The rotor comprises a hub with a plurality of blades formed around the hub. The stator comprises a stator coil assembly and a PCB (printed circuit board) having a circuit to control electrical current flowing through the coil.

Referring to FIG. 8, a conventional PCB 1 for such a fan is illustrated. The PCB 1 is configured to have an annular shape. A round hole 10 is usually defined at a center portion of the PCB 1. This round hole 10 is for allowing an axial tube of the fan to extend therethrough. A plurality of electronic components is mounted on the PCB 1. These electronic components comprise two diodes 11, 12, a Hall effect sensor 13, a driver IC 14, a compactor 15, a resistor 16 and three mounting holes 17a, 17b, 17c for receiving terminals of the coils of the stator coil assembly. Person skilled in the pertinent art should know the action of these electronic components. Therefore, a detailed description for these electronic components is omitted.

FIG. 9 is a view showing a layout of a plurality of PCBs 1 on a substrate 20. Reference numeral 23 denotes the annular areas the PCBs 1 occupy, reference numeral 21 denotes the areas corresponding to the round hole 10 of the PCBs 1, and reference numeral 22 denotes the areas existing between the PCBs 1 due to the annular shape of the PCBs 1. In producing the PCBs 1, only the annular areas 23 of the substrate 20 are cut out from the substrate 20 to form the PCBs 1, while the rest areas 21, 22 of the substrate 20 form no part of the PCBs 1 and are therefore wasted.

Referring to FIG. 10, U.S. Pat. No. 5,925,948 discloses a fan motor having a semicircular PCB (not labeled). A Hall effect sensor 13′ and a driver IC 14′ are mounted on the PCB. Except the Hall effect sensor 13′, the electronic components as shown in FIG. 8 are integrated into the driver IC 14′. In producing the PCB from a substrate, a considerable area of the substrate is still wasted due to semicircular shape of the PCB.

For the foregoing reasons, there is a need for a fan having a PCB which can reduce or eliminate the waste of the substrate material.

### SUMMARY OF THE INVENTION

The present invention is directed to a fan having a printed circuit board shaped to save substrate material.

A fan in according the present invention comprises a stator comprising a stator coil assembly having a plurality of coils, and a circuit board providing a circuit to control the electrical current flowing through the coils, and a rotor comprising a hub carrying a permanent magnet facing to the stator coil assembly. At least two sides of the circuit board are substantially straight so that a plurality of such printed circuit boards can be compactly laid out side by side on a substrate for producing the printed circuit boards.

Other objects, advantages and novel features of the present invention will be drawn from the following detailed description of the preferred embodiments of the present invention with attached drawings, in which:

### BRIEF DESCRIPTION OF THE DRAWINGS

FIG. 1 is a cross sectional view of a fan according to a preferred embodiment of the present invention;

FIG. 2 is an enlarged exploded, isometric view of the PCB of the fan of FIG. 1;

FIG. 3 is a diagram showing the drive and control circuit of the fan;

FIG. 4 is a view showing a layout of a plurality of PCBs of FIG. 2 on a substrate;

FIGS. 5-7 respectively shows a PCB of the fan of the present invention according to alternative embodiments;

FIG. 8 is a plane view of a PCB of a conventional fan;

FIG. 9 is a view showing a layout of a plurality of PCBs of FIG. 8 on a substrate; and

FIG. 10 is a plane view of a PCB of another conventional fan.

### DESCRIPTION OF PREFERRED EMBODIMENTS

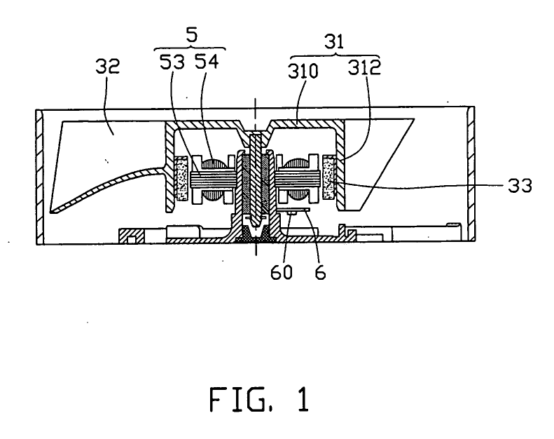

Referring to FIG. 1, a fan comprises a stator and a rotor rotatable with respect to the stator.

The rotor comprises a cup-shaped hub 31 having a top wall 310 and a periphery wall 312 depending from the top wall 310, and a plurality of blades 32 formed around the peripheral wall 312 of the hub 31. A permanent magnet 33 is attached to an inside of the peripheral wall 312 of the hub 31.

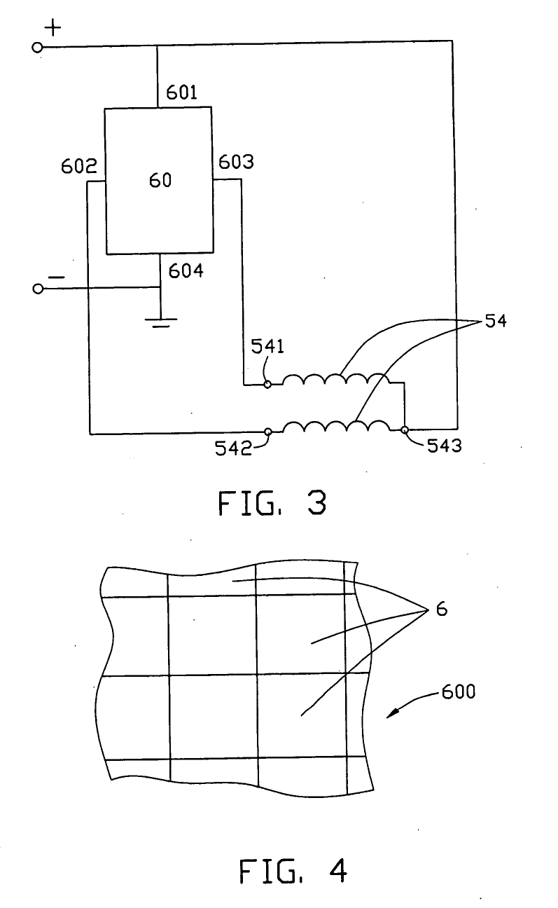

The stator comprises a coil assembly 5 and a PCB 6 (Printed Circuit Board) having a circuit to control electrical current to flow through the coils of the coil assembly 5. The coil assembly 5 comprises a stator core 53 having a plurality of arms, and a plurality of coils 54 wound around the arms of the stator core 53. The coils 54 have three terminals 541, 542, 543 (FIG. 3) connected to the PCB 6.

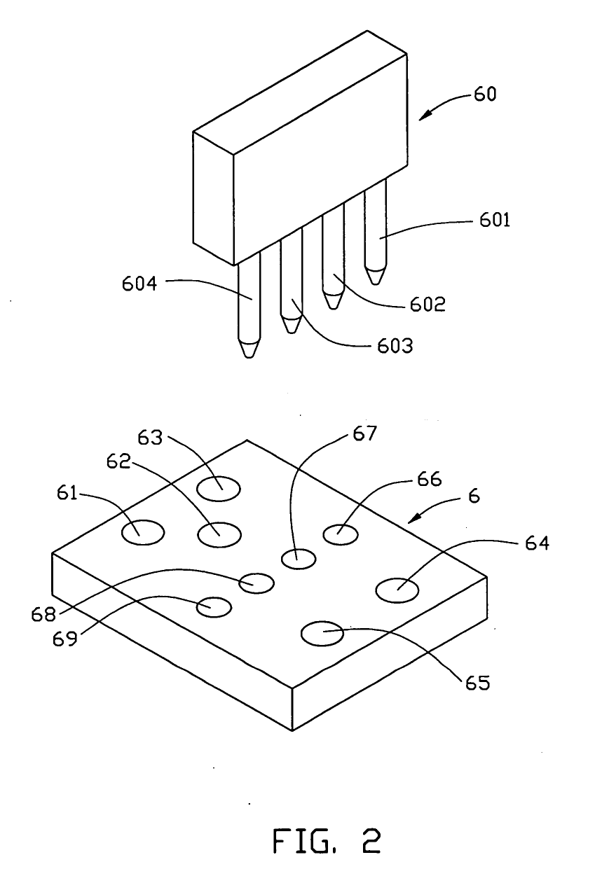

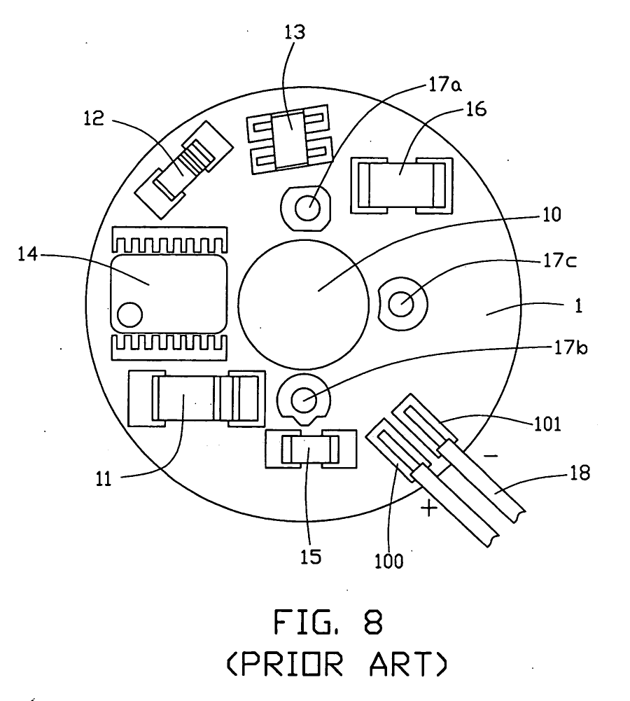

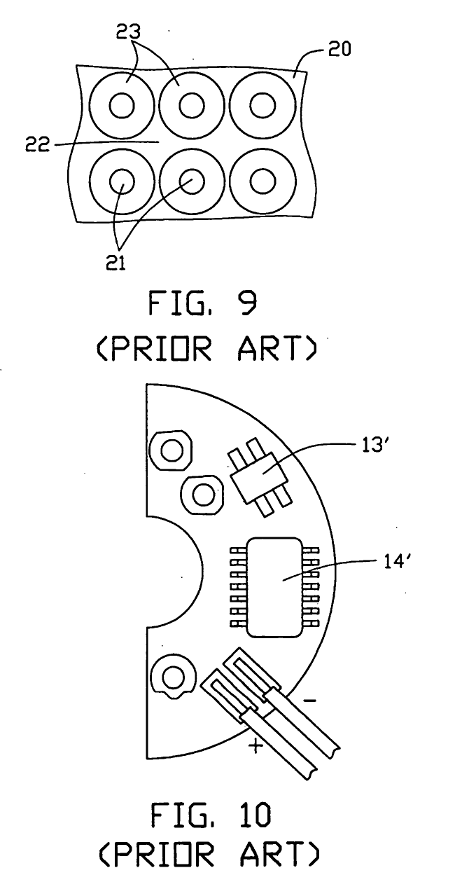

Referring to FIG. 2, the PCB 6 has a rectangular shape, i.e., four sides of the PCB 6 are straight. Three mounting holes 61, 62, 63 are defined in the PCB 6, for insertion of the terminals 541, 542, 543 of the coils 54 (FIG. 3). An IC 60 (Integrated Circuit) is mounted onto the PCB 6. The electronic components on the PCB 1 as shown in FIG. 8, i.e., the diodes 11, 12, the Hall effect sensor 13, the driver IC 14, the compactor 15, the resistor 16, are integrated into the IC 60. In the preferred embodiment, the model number of the IC 60 is ATS276, which is manufactured by Anachip T. The IC 60 has four terminals 601, 602, 603, 604. The PCB 6 defines four connecting holes 66, 67, 68, 69, for respective insertion of the terminals 601, 602, 603, 604. Two connecting holes 64, 65 are defined in the PCB 6, for receiving source terminals of plus and minus sides respectively.

FIG. 3 shows a block diagram of the fan. The source terminal of plus side connects to the terminal 601 of the IC 60 and the common terminal 543 of the coil 54. The source terminal of minus side connects to the terminal 604 and is grounded. The terminals 602, 603 connect respectively to the other two terminals 541, 542 of the coils 54. During operation of the IC 60, electrical current alternatingly flows through each of the coils 54 to generate alternating magnetic fields. The alternating magnetic fields interact with the permanent magnetic field of the permanent magnet 33 to drive the rotor to rotate.

FIG. 4 shows a layout of a plurality of PCBs 6 on a substrate 600. Since the electronic components are integrated into the IC 60, the PCB 6 can have a greatly reduced area so that the PCB 6 may be mounted beside an axial tube of the fan without forming the round center hole 10 as shown in FIG. 8. Specifically, the area of the PCB 6 may be as small as 5% to 16% of the area of the top wall 310 of the hub 31. In addition, the sides of the PCB 6 are straight; so all PCBs 6 can be compactly laid out side by side on the substrate 600 without spare portion formed on the substrate 600 to be wasted. Therefore, the substrate 600 is fully utilized.

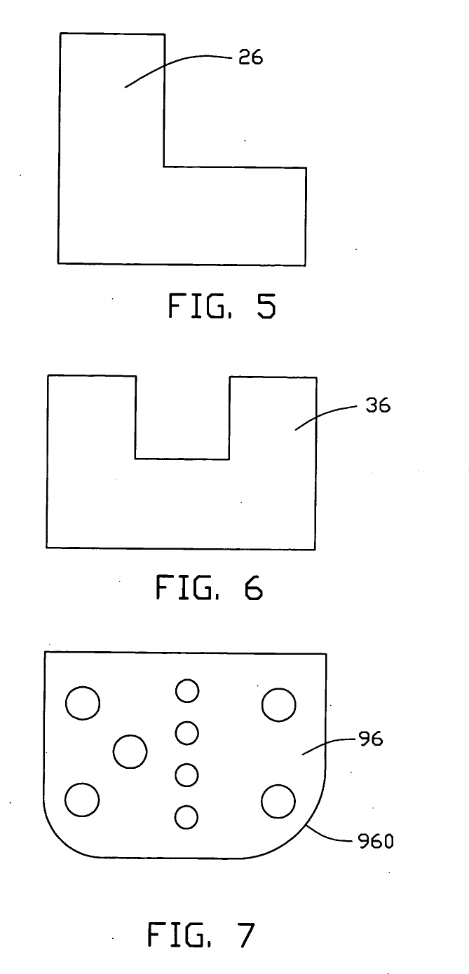

FIGS. 5 and 6 respectively illustrate PCBs 26, 36 having shapes of letters L and U according to alternative embodiments of the present invention. Both of the PCBs 26, 36 have straight sides; the substrate can thus be fully utilized in producing the PCBs 26, 36.

In the embodiments illustrated above, all sides of the PCBs 6, 26, 36 are straight. As a result, no portion of the substrate is wasted in producing the PCBs 6, 26, 36. Understandably, in order to comply with other components of the fan, the shape of the PCB may be slightly changed, as long as it will not cause a considerable waste of the substrate material in producing these PCBs. FIG. 7 illustrates a PCB 96 according to a further alternative embodiment of the present invention. The PCB 96 comprises a pair of round corners 960. Except that the PCB 96 has two round corners, the other sides of the PCB 96 are straight. Therefore, in producing the PCB 96, only a few portion of the substrate that is between the round corners 960 of adjacent PCBs 96 have to be wasted.

In a still alternative embodiment of the present invention, one or more sides of the PCB is/are not absolutely straight, but slightly arcuate. However, the arcuate sides should be designed so as not to cause a considerable waste of the substrate in producing these PCBs.

It is understood that the invention may be embodied in other forms without departing from the spirit thereof. The above-described examples and embodiments are to be considered in all respects as illustrative and not restrictive, and the invention is not to be limited to the details given above.

1. A fan comprising:
a stator comprising a stator coil assembly having a plurality of coils, and a circuit board providing a circuit to control the electrical current flowing through the coils, at least two sides of the circuit board being substantially straight; and
a rotor comprising a hub carrying a permanent magnet facing to the stator coil assembly.

2. The fan as described in claim 1, wherein the circuit board is rectangular.

3. The fan as described in claim 2, wherein the hub comprises a top wall and a peripheral wall extending from the top wall, and the area of the circuit board is as small as 5% to 16% of the area of the top wall.

4. The fan as described in claim 1, wherein the circuit board has a shape of letter L.

5. The fan as described in claim 1, wherein the circuit board has a shape of letter U.

6. The fan as described in claim 1, wherein the circuit board comprises a round corner.

7. The fan as described in claim 1, wherein an IC is mounted to the circuit board, and the IC is integrated with a Hall sensor and a driver circuit of the fan.

8. A motor comprising:
a printed circuit board comprising an IC mounted thereon, the IC integrated with a Hall sensor and a driver circuit of the motor, the printed circuit board being shaped so that a plurality of such printed circuit boards can be compactly laid out side by side on a substrate for producing the printed circuit boards;
a stator coil assembly having a plurality of coils electrically connected to the driver circuit of the printed circuit board to produce alternating magnetic fields when the coils are charged with electrical currents under control of the IC; and
a rotor comprising a permanent magnet generating permanent magnetic field to interact with the alternating magnetic fields of the stator.

9. The motor as described in claim 8, wherein at least two sides of the printed circuit board are substantially straight.

10. The motor as described in claim 9, wherein the printed circuit board is rectangular.

11. The motor as described in claim 9, wherein the printed circuit board is L-shaped.

12. The motor as described in claim 9, wherein the printed circuit board is U-shaped.

13. The motor as described in claim 9, wherein the printed circuit board has a round corner.

14. A method to manufacture motor-use printed circuit boards (PCBs), comprising:
providing a substrate as raw material to make said PCBs;
shaping said PCBs on said substrate so that each PCB compactly borders with at least two neighbor PCBs on said substrate; and
cutting off said PCBs from said substrate respectively.

15. The method as described in claim 14, wherein at least two sides of said each PCB are substantially straight.

16. The method as described in claim 14, wherein said each PCB is shaped as one of a rectangular board, an L-shaped board and a U-shaped board.

17. The method as described in claim 14, further comprising the step of installing said each PCB in a fan-motor hub so that an occupied area of said each PCB is 5% to 16% of an area of a top wall of said hub.
